(19) United States
(12) Patent Application Publication
(10) Pub. No.: US 2012/0049706 A1
(43) Pub. Date: Mar. 1, 2012

(54) Air Flow Management Enclosure

(75) Inventors: Carl Cottuli, Franklin, MA (US); Manuel D. Linhares, JR., Coventry, RI (US)

(73) Assignee: Eaton Corporation, Cleveland, OH (US)

(21) Appl. No.: 13/222,702

(22) Filed: Aug. 31, 2011

Related U.S. Application Data
(60) Provisional application No. 61/378,816, filed on Aug. 31, 2010.

(51) Int. Cl. H05K 7/20; H05K 5/02

(52) U.S. Cl. 312/236; 211/26

(57) ABSTRACT

A frame for use with cabinets and enclosures that house electronic equipment to prevent warm air from entering into, and cool air from exiting out of, the cabinet through gaps between the structural members of the cabinet. The frame is a singular piece of material that replaces, and provides the functions of, both vertical and horizontal structural members, and may also include EIA-standard mounting holes. The top and bottom of the frame's interior may be concave to direct cooling air into, or heated air out of, the cabinet. Alternatively, a pair of angled vertical rails may be mounted to the vertical structural members of the cabinet to block the air gaps.

### CROSS-REFERENCE TO RELATED APPLICATION

This application claims priority to U.S. Provisional Patent Application Ser. No. 61/378,816, entitled “Air Flow Management Enclosure,” filed on Aug. 31, 2010. The entire contents of the priority application are expressly incorporated by reference herein.

### FIELD OF THE INVENTION

The invention relates to cabinets and enclosures for housing rack-mounted electrical and computer equipment.

### BACKGROUND OF THE INVENTION

Electronic equipment components or devices, such as computer servers, data storage devices, and power supplies, are often mounted on and supported by a rack or frame using mounting members such as shelves, rails and/or brackets. As is well known, these electronic components generate substantial heat that must be dissipated in order to maintain the devices in proper working order and prevent damage and possible failure. Most electronic device manufacturers require air of a specific temperature range to be drawn into the front of the device, passed over the internal components where the heat is exchanged, and exhausted out of the back of the device. Cabinets and enclosures, as well as the data centers or rooms that house the cabinets and enclosures, are typically set up to accommodate this “front to back” air flow requirement, although other configurations, such as “back to front,” are often employed.

Properly exhausting the heated air generated within the cabinets becomes increasing more difficult as more powerful equipment is installed in the cabinets, and as the cabinets become more densely packed with electronic equipment. As a result, the inlet temperature of the air drawn into the devices is more likely to exceed the recommended operating range of the device. The result is an upward trend in the failure of these electronic devices. Such equipment failures are more than an inconvenience, as some failures may result in interruptions to mission critical systems and communications, such as those used for example in emergency response management, aviation and flight control, process control, and finance.

The problems associated with heat dissipation are compounded when the racks or frames are not fully populated with components, resulting in vacant sections. This empty space may result in warm air from the back being drawn into the air intake at the front, which prevents cooler air from being drawn into the equipment, and may cause the equipment to overheat. One of the most common solutions to this problem is to attach blanking panels to the rails or brackets of the enclosure to function as a barrier to block or fill in these vacant sections. The use of blanking panels, however, is not a complete solution.

With or without blanking panels, warm air may be drawn into the cabinet or enclosure from the spaces between the rails, corner supports and other structural elements, and from the sides of the enclosure. There is a need in the art, then, for a cabinet or enclosure that better prevents warm air from entering into the cabinet through such gaps, and conversely, prevents cooling air from escaping through these gaps as it enters the cabinets.

As is also known in the art, the cooling air that is directed into a cabinet or enclosure is often not properly directed to the electronic equipment. For example, cooling air entering the top or bottom of a cabinet may pass over or under the equipment, respectively, rather than into the equipment's airflow intake. Cooling air may also not be fully utilized when it merely passes along the left and right sides of a cabinet. There is a need in the art, then, for a cabinet or enclosure with features that direct cooling air to the electronic equipment.

In addition, the air heated by the electronic equipment is often not properly exhausted from the cabinet or enclosure. For example, heated air may circulate on the sides of the cabinet, or at the top or bottom of the cabinet. There is a need in the art, then, for a cabinet or enclosure with features that direct heated air away from the electronic equipment and out of the cabinet or enclosure.

As is known in the art, cabinets and enclosures are often required to satisfy one or more industry standards, such as the Electronic Industries Association (EIA) EIA-310-D standard. This standard defines requirements for the industry-standard nineteen-inch rack, and in particular, establishes parameters for the rail mounting-hole patterns. Cabinets and enclosures directed to addressing the issues of air flow management should also comply with these standards.

### SUMMARY OF THE INVENTION

The invention disclosed herein provides cabinets and enclosures for housing rack-mounted electrical and computer equipment with improved air flow distribution features.

In preferred embodiments, the cabinets and enclosures, and in particular the inventive frame members and vertical rack mount rails, disclosed herein offer a number of advantages, in particular:

1. Air flow separation—cooling air is prevented from mixing with the heated air;

2. Passive airflow management—the cabinets and enclosures do not require additional active components to manage airflow;

3. Air flow direction—cooling air is directed to the electronic equipment and heated air is directed away from the electronic equipment;

4. EIA/ECA compatibility—the cabinets and enclosures support the Electronic Industries Association (EIA) and Electronic Components Association (ECA) standards;

5. Dual Purpose—the inventive frame members and vertical rack mount rails may be installed at the front of the cabinet or at the back of a cabinet, and may be configured to support both front-to-back or back-to-front cooling;

6. Adjustable—the inventive frame members may be manufactured with multiple mounting offset settings and rail positions, and with or without integrated vertical rack mount rails. The inventive vertical rack mount rails may also be manufactured with multiple offset settings.

7. Uni-frame construction—the inventive frame members and vertical rack mount rails are configured to minimize the number of required parts while providing the strength needed to support the electronic equipment;

8. Cost effective—fewer parts reduces cost and manufacturing waste;

9. Material selection—the inventive frame members and vertical rack mount rails may be constructed in multiple materials to satisfy cost and environmental requirements, including but not limited to steels, aluminum, plastic, and reinforced plastic; and

10. Manufacturing methods—the inventive frame members and vertical rack mount rails may be constructed through multiple methods to satisfy cost and environmental requirements including but not limited to rotation molding, compression molding, blow molding, casting, deep draw methods, stamping, and vacuum-forming.

In a preferred embodiment, the invention provides an assembly for use with a housing, the housing defining an interior that is adapted to hold heat-generating electronic equipment and a first opening that leads to the housing interior. The assembly comprises a frame external to the housing and defines a second opening. The frame is adapted to be coupled to the housing, such that the frame encompasses the first opening, and the first opening is in fluid communication with the second opening. The second opening defines a height and width that are smaller than the height and width of the first opening.

In an aspect, at least a portion of the second opening is defined by a curved surface of the frame. In another aspect, the curved surface is a concave surface. In yet another aspect, at least a portion of the frame defines a sloped surface.

In an aspect, the frame has a generally parallelepiped shape defined by a top outer surface, a bottom outer surface, and two opposing side outer surfaces, and the second opening is generally rectangular in shape and is defined by a top inner surface, a bottom inner surface, and two opposing side inner surfaces.

In another aspect, at least one of the top inner surface, the bottom inner surface, and the opposing side inner surfaces is a sloped surface. In yet another aspect, at least one of the top inner surface, the bottom inner surface, and the opposing side inner surfaces is a curved surface. In still another aspect, the curved surface is a concave surface. In an additional aspect, at least the top inner surface and the bottom inner surface are concave surfaces that each terminate in a generally flat protrusion.

In an aspect, the frame further defines two opposed rows of mounting holes, where each row of mounting holes is contiguous with one of the side inner surfaces. In another aspect, the opposed rows of mounting holes are offset from a front face of the frame.

In an additional preferred embodiment, the invention provides an assembly for use with a housing, the housing defining an interior that is adapted to hold heat-generating electronic equipment and a first opening that leads to the housing interior. The assembly comprises a frame external to the housing that defines a second opening, where the frame is adapted to be coupled to the housing, such that the frame encompasses the first opening and the first opening is in fluid communication with the second opening. The frame has a generally parallelepiped shape defined by a top outer surface, a bottom outer surface, and two opposing side outer surfaces. The second opening is generally rectangular in shape and is defined by a curved top inner surface, a curved bottom inner surface, and two opposing curved inner bottom surfaces, and the second opening defines a height and width that are smaller than the height and width of the first opening. The frame further defines two vertical opposed rows of mounting holes that are offset from a front face of the frame, and the mounting holes are configured to at least partially support the electronic equipment.

In an aspect, the top inner surface and the bottom inner surface are concave surfaces that each terminate in a generally flat protrusion that extends into the interior of the housing. In another aspect, at least one of the top inner surface, the bottom inner surface, and the opposing side inner surfaces is a sloped surface.

In another preferred embodiment, the invention provides an enclosure defining an interior that is adapted to hold heat-generating electronic equipment. The enclosure comprises a first frame having a generally parallelepiped shape defined by a top outer surface, a bottom outer surface, and two opposing side outer surfaces. The first frame defines a generally rectangular opening in fluid communication with the interior, the opening defined by a top inner surface, a bottom inner surface, and two opposing side inner surfaces. The first frame further defines two opposed rows of mounting holes, where each row of mounting holes is contiguous with one of the side inner surfaces. The enclosure further comprises a pair of opposed horizontally-mounted rail tracks, where a first end of each rail track is coupled to the first frame, and a pair of opposed vertical rack mount rails, where each rack mount rail is coupled to one of the rail tracks, and each of the rack mount rails defines a plurality of mounting holes. The mounting holes defined in the first frame and the mounting holes defined in the rack mount rails are configured to hold the heat-generating equipment.

In an aspect, the enclosure further comprises a second frame opposite the first frame, where the second frame defines a generally rectangular opening in fluid communication with the interior, and where a second distal end of each of the rail tracks is coupled to the second frame. In another aspect, at least one of the top inner surface, the bottom inner surface, and the opposing side inner surfaces is a curved surface. In an additional aspect, the top inner surface and the bottom inner surface of the first frame are concave surfaces that each terminate in a generally flat protrusion that extends into the interior of the enclosure.

In yet another preferred embodiment, the invention provides an enclosure defining an interior that is adapted to hold heat-generating electronic equipment. The enclosure comprises a generally parallelepiped framework comprised of two pairs of opposed vertical structural members and two pairs of opposed horizontal structural members. The enclosure further comprises a pair of vertical rails, where each vertical rail defines a first end and a second distal end, and each vertical rail forms an obtuse angle along its length and further defines a plurality of mounting holes proximate the second distal end. The first end of each vertical rail is adapted to be coupled to one of the pair of opposing vertical structural members, and the second distal end of each vertical rail extends into the interior of the enclosure. The mounting holes in the vertical rails are configured to hold the heat-generating equipment.

In an aspect, at least one of the pairs of opposing vertical structural members defines a plurality of mounting holes, such that the mounting holes in the vertical structural members and the mounting holes in the vertical rails are configured to hold the heat-generating equipment.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1A is a perspective view of a prior art cabinet or enclosure;

FIG. 1B is a front view of a prior art cabinet or enclosure;

FIG. 2 is perspective view of a preferred embodiment of a cabinet or enclosure with inventive frame members;

FIG. 3 is a perspective view of one of the frame members of the cabinet or enclosure of FIG. 2;

FIG. 4 is front view of the frame member of FIG. 3;

FIG. 5 is a side view of the frame member of FIG. 3;

FIG. 6 is a top view of the frame member of FIG. 3;

FIG. 7 is a rear view of the frame member of FIG. 3;

FIG. 8 is a cross-sectional view taken along line “8-8” of the frame member of FIG. 4;

FIG. 9 is a detailed view of the portion “FIG. 9” shown circled in FIG. 8;

FIG. 10 is a cross-sectional view taken along line “10-10” of the frame member of FIG. 4;

FIG. 11 is a detailed view of the portion “FIG. 11” shown circled in FIG. 10;

FIGS. 12A and 12B are detailed views of the portion “FIG. 12” shown circled in

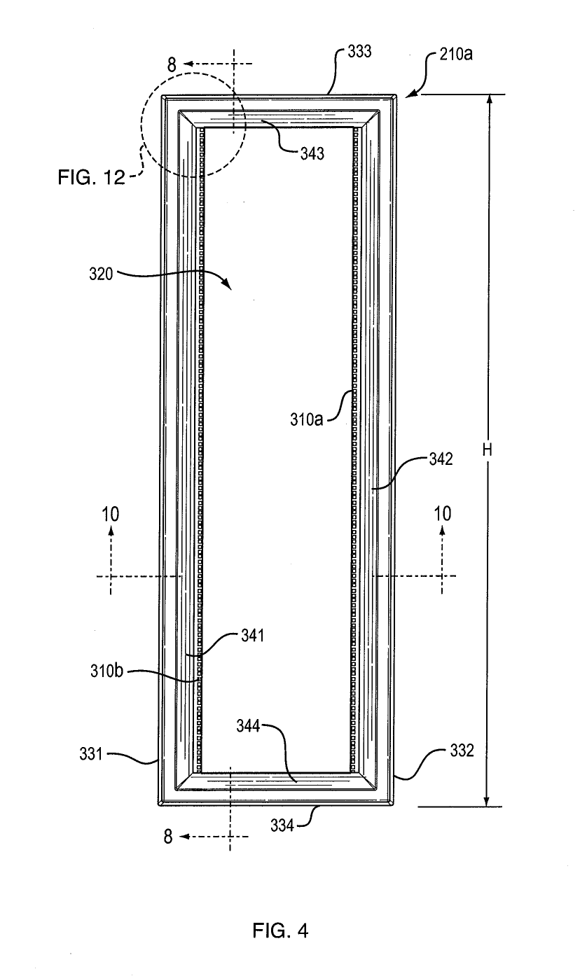

FIG. 4;

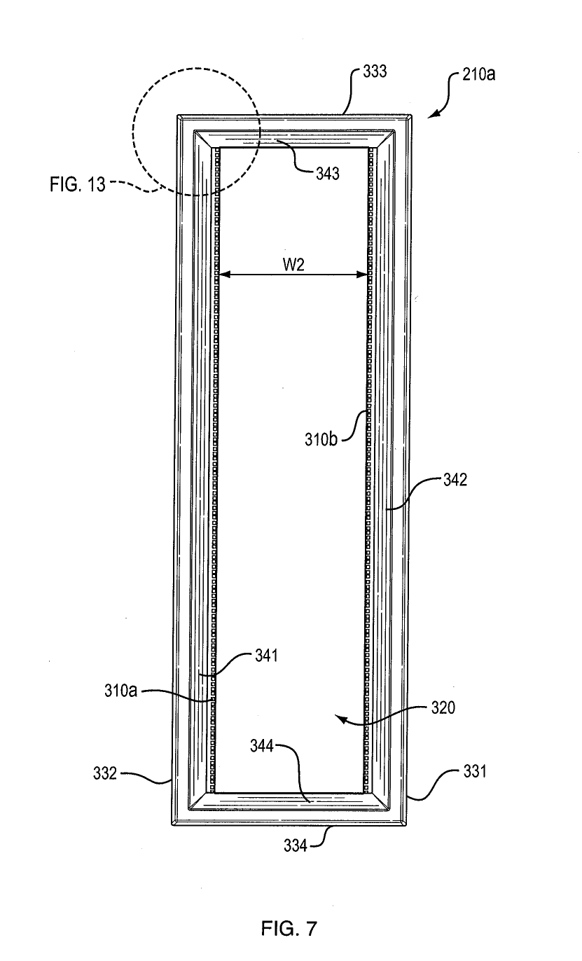

FIG. 13 is a detailed view of the portion “FIG. 13” shown circled in FIG. 7;

FIG. 14 is a is perspective view of a preferred embodiment of a cabinet or enclosure with inventive vertical rack mount rails;

FIG. 15 is a top view of a portion of the cabinet or enclosure of FIG. 14, showing one embodiment of the inventive vertical rack mount rail; and

FIG. 16 is a top view of an alternative embodiment of the inventive vertical rack mount rail of FIG. 14.

### DETAILED DESCRIPTION OF THE PREFERRED EMBODIMENTS OF THE INVENTION

### I. Prior Art Cabinet or Enclosure

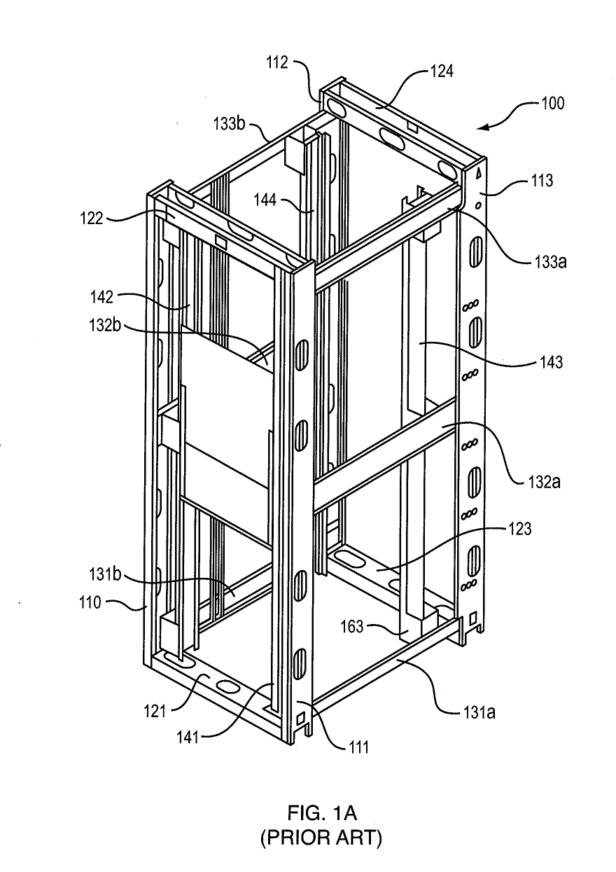

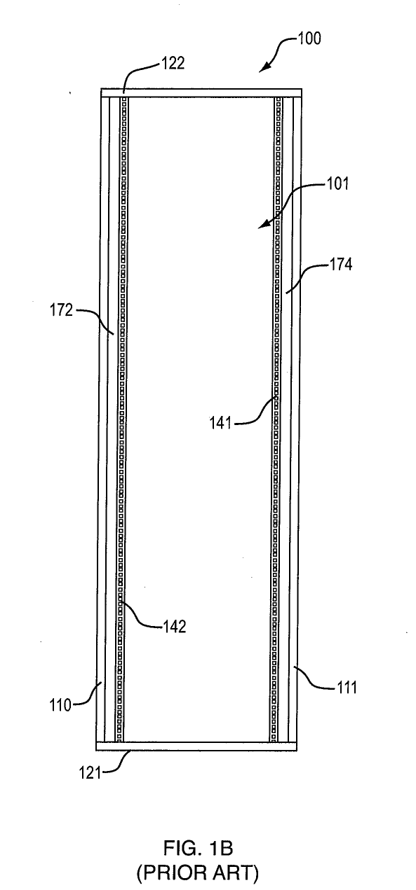

A prior art cabinet or enclosure 100 is shown in FIGS. 1A and 1B. As is known in the art, cabinet or enclosure 100 is a housing adapted to hold heat-generating electronic equipment within its interior. Cabinet or enclosure 100 comprises two vertical front enclosure structural members 110 and 111, two vertical rear enclosure structural members 112 and 113, two horizontal front enclosure structural members 121 and 122, and two horizontal rear enclosure structural members 123 and 124. The enclosure structural members (110, 111, 112, 113, 121, 122, 123, and 124) together form the parallelepiped exterior frame of prior art cabinet or enclosure 100.

Prior art cabinet or enclosure 100 also comprises three pairs of prior art horizontally-mounted rail tracks: lowermost rail tracks 131a and 131b, center rail tracks 132a and 132b, and uppermost rail tracks 133a and 133b. The pairs of horizontally-mounted rail tracks are mounted parallel to each other in a front-to-back orientation, along the left and right sides of prior art cabinet or enclosure 100.

Prior art cabinet or enclosure 100 further comprises two pairs of prior art vertical rack mount rails: front rack mount rails 141 and 142, and rear rack mount rails 143 and 144. Two of the vertical rack mount rails are installed on the left interior side of cabinet or enclosure 100 (142 and 144), and the other two vertical rack mount rails are installed on the right interior side of cabinet or enclosure 100 (141 and 143). The vertical rack mount rails are coupled to the horizontally-mounted rail tracks by connectors known in the art, such as connector 163. Prior art cabinet or enclosure 100 may comprise additional pairs of vertical rack mount rails as necessary for mounting and supporting the electronic equipment within the enclosure.

As shown in FIG. 1B, cabinet or enclosure 100 defines an opening 101 that leads to the interior of the enclosure. As further shown in FIG. 1B, there is a gap 172 between vertical front enclosure structural member 110 and front rack mount rail 142, and a similar gap 174 between vertical front enclosure structural member 111 and front rack mount rail 141. While not shown in FIG. 1B, similar gaps exist between vertical rear enclosure structural member 112 and rear rack mount rail 144 and vertical rear enclosure structural member 113 and rear rack mount rail 143. These gaps allow cooling air to bypass the electrical components and permit heated air to recirculate from front to back, along the sides, to the front of the cabinet, to be drawn into the air intake of the electrical components.

II. Cabinet or Enclosure with Air Flow Management Features—Frame Members

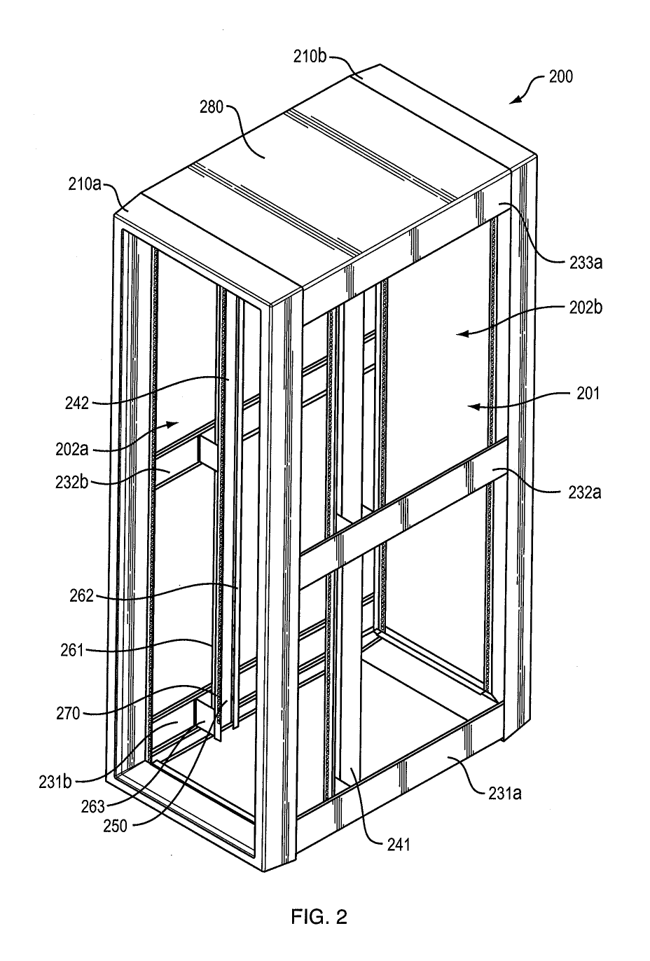

A preferred embodiment of an inventive cabinet or enclosure 200 with inventive air flow management features is shown in FIG. 2. As with prior art cabinet 100, cabinet or enclosure 200 comprises a housing that is adapted to hold heat-generating electronic equipment within its interior 201, and defines front and rear openings 202a and 202b, respectively, that lead to the interior 201 of the cabinet.

Cabinet or enclosure 200 further comprises two identical frame members 210a and 210b: front frame member 210a at the front of the cabinet, and rear frame member 210b at the rear of the cabinet. In alternate embodiments, cabinet or enclosure 200 may comprise only one frame member, located at either the front or the rear of the cabinet. Frame members 210a and 210b are adapted to be coupled to front and rear of the housing, such that frame member 210a encompasses opening 201a and frame member 210b encompasses opening 201b.

As discussed in detail below, a frame member (210a, 210b) is a singular piece of material that provides the structural functions of both the vertical and horizontal enclosure structural members of the prior art cabinet or enclosure 100 shown in FIG. 1A. For example, in preferred embodiments, front frame member 210a provides the structural functionality of vertical front enclosure structural members 110 and 111 and horizontal front enclosure structural members 121 and 122. Similarly, rear frame member 210b provides the structural functionality of vertical rear enclosure structural members 112 and 113 and horizontal rear enclosure structural members 123 and 124. Note that frame members 210a and 210b are identical, except for their placement relative to cabinet or enclosure 200.

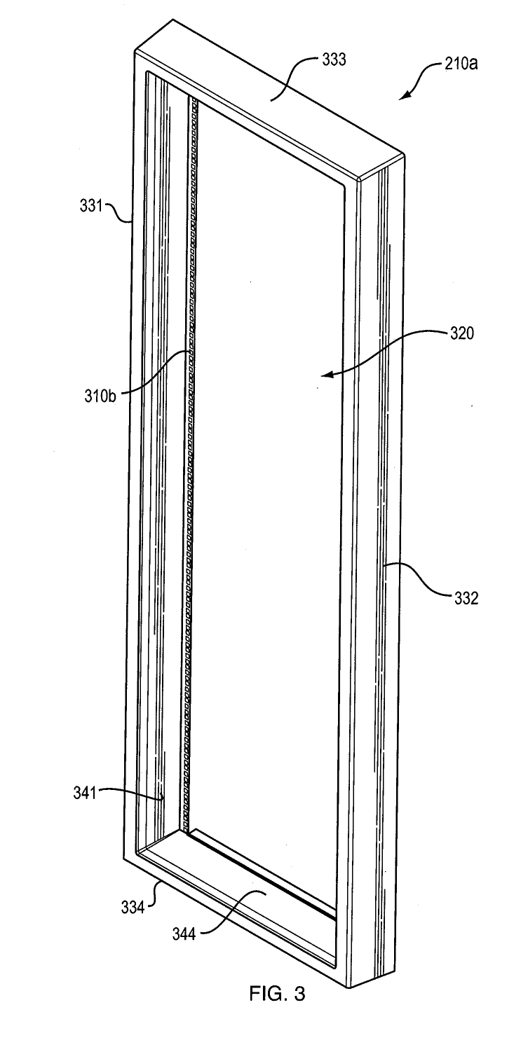

In preferred embodiments, frame members 210a and 210b each define a plurality of mounting holes configured and adapted for mounting and supporting the electronic equipment, as would be provided by a pair of opposed vertical rack mount rails (front rack mount rails 141 and 142, rear rack mount rails 143 and 144) in prior art cabinet or enclosure 100. In this case, the frame members accomplish the functionality of both the vertical enclosure structural members and the vertical rack mount rails. For example, with reference to FIGS. 3, 4 and 7, frame member 210a defines two vertical, opposing rows of mounting holes 310a and 310b. Note that, in alternate embodiments, either or both of the frame members (210a, 210b) may be configured with or without the rows of mounting holes. Note also that the opposing rows of mounting holes 310a and 310b may be offset from the front face of the frame member. This configuration provides a space of approximately two inches (5.1 centimeters) between the front face of the frame member and the rows of mounting holes to accommodate cabling.

With further reference to FIG. 2, cabinet or enclosure 200 also preferably comprises three pairs of horizontally-mounted rail tracks: lowermost rail tracks 231a and 231b, center rail tracks 232a and 232b, and uppermost rail tracks 233a and 233b (not shown). The pairs of horizontally-mounted rail tracks are preferably mounted parallel to each other in a front-to-back orientation, along the left and right sides of cabinet or enclosure 200, and are coupled to the frame members 210a and 210b. The horizontally-mounted rail tracks preferably span the approximate interior width of cabinet or enclosure 200. Note that neither the number of horizontally-mounted rail tracks, nor their placement within the cabinet or enclosure, is a limitation of the invention.

In a preferred embodiment, cabinet or enclosure 200 also comprises a pair of vertical rack mount rails 241 and 242. Vertical rack mount rails 241 and 242 are preferably mounted parallel to each other, one each on the left and right sides of the cabinet or enclosure 200, and are coupled to the horizontally-mounted rail tracks (231a, 231b, 232a, 232b, 233a and 233b) by connectors known in the art, such as connector 263. The vertical rack mount rails preferably span the approximate interior height of the cabinet or enclosure, from the lowermost rail tracks (231a, 231b) to the uppermost rail tracks (233a, 233b). Note that neither the number, nor the configuration, of the vertical rack mount rails is a limitation of the invention.

The vertical rack mount rails 241 and 242 are of the type known in the art, and define an elongated body 250 and a pair of generally opposed flanges 261 and 262. In a preferred embodiment, flanges 261 and 262 extend substantially along the length of the vertical rack mount rail. Either or both of flanges 261 and 262 may define a plurality of mounting holes 270 configured for mounting and supporting the electronic equipment.

In a preferred embodiment, the vertical rack mount rails satisfy the Electronic Industries Association (EIA) EIA-310-D standard, which defines requirements for the industry-standard nineteen-inch rack, and in particular, establishes parameters for the vertical rack mount rail mounting-hole patterns.

Cabinet or enclosure 200 also comprises optional ceiling or top member 280. In alternate embodiments, the top of cabinet or enclosure 200 may be open to a duct, chimney, plenum or alternate air flow management device.

### III. Frame Member

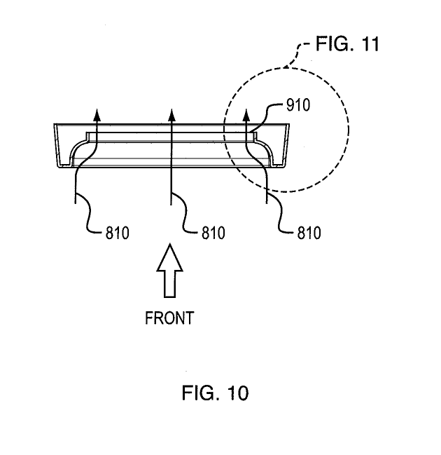

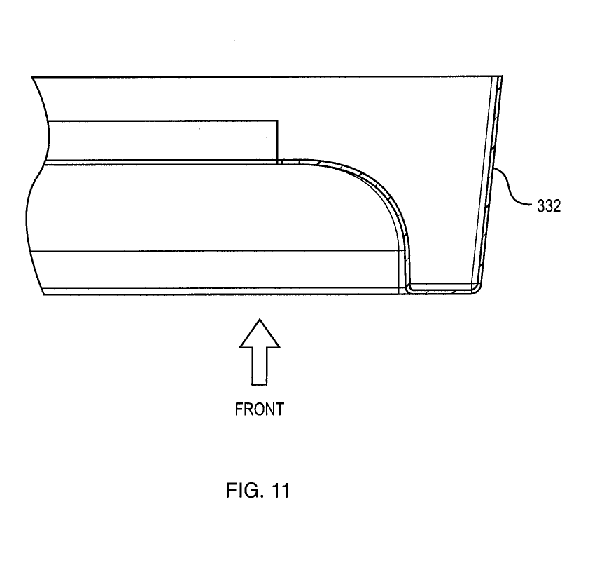

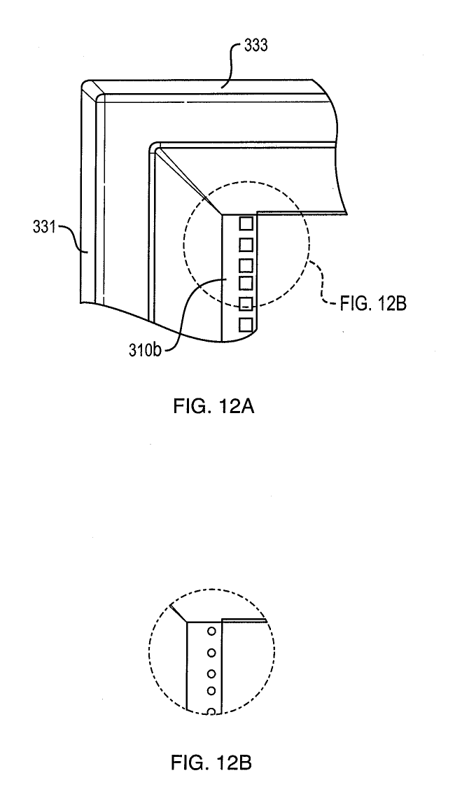

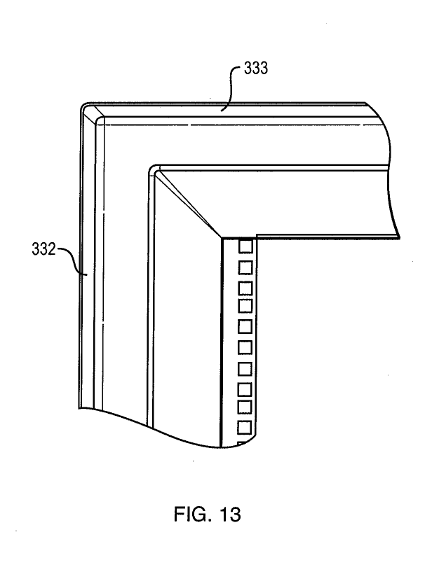

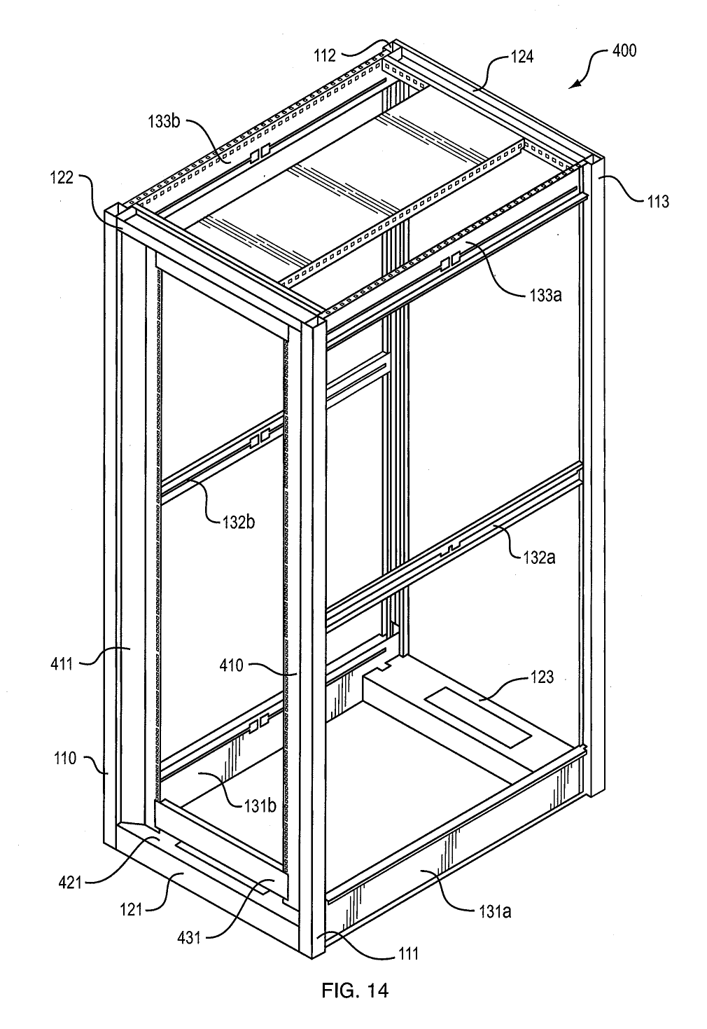

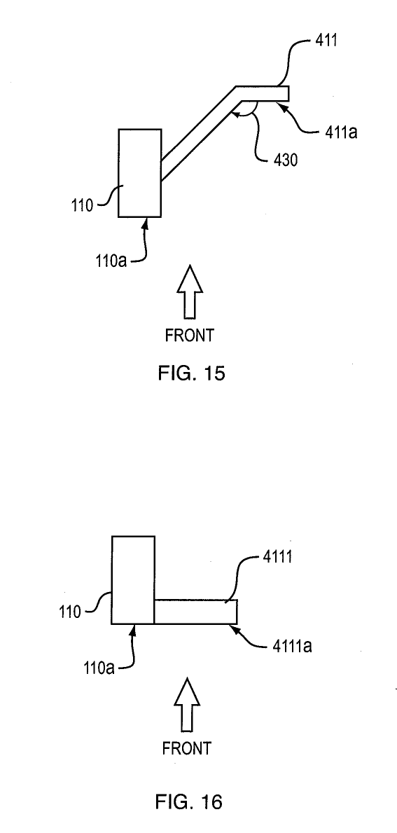

Front frame member 210a is described in detail below, with reference to FIGS. 3-13. As previously noted, front frame member 210a and rear frame member 210b are structurally identical, and differ only in their placement relative to cabinet or enclosure 200.

Frame member 210a defines an opening or open area 320 configured to receive and direct cooling air into the front portion of the interior of the cabinet or enclosure 200. Open area 320 defines a height and width that are preferably smaller than the height and width of the opening 202a to the interior 201 of the enclosure, as shown in FIG. 4 and described in detail below.

When installed at the front of the cabinet in a front-to-back cooling configuration, as shown in FIG. 2, frame 210a functions to force cooling air to flow across the equipment's airflow intake rather than along the sides of the equipment. Frame member 210a also functions to eliminate the gaps 172 and 174 of prior art cabinet or enclosure 100, as shown in FIG. 1B.

Note that the frame members (210a, 210b) are reversible. When installed at the back of the cabinet in a front-to-back cooling configuration, as is frame member 210b in FIG. 2, the open area 320 is configured to direct heated air away from the interior of the cabinet or enclosure 200.

As shown in FIG. 4, the height H of open area 320 is at least equal to:

(n*U), where:

U is the height of a rack unit (also referred to as RU), a unit of measure known in the art and used to describe the height of equipment to be mounted in a standard 19-inch (48.3 centimeters) or standard 23-inch (58.4 centimeters) wide cabinet or enclosure. As is known in the art, one rack unit (U or RU) is 1.75 inches or 4.4 centimeters; and

n is the number of rack units.

As shown in FIG. 6, the width W1 of frame 210a is preferably greater than or equal to approximately 24 inches (61 centimeters).

As shown in FIG. 7, the width W2 between the two rows of mounting holes 310a and 310b is approximately between 17.72 and 22.7 inches (45 centimeters and 57.7 centimeters).

With further reference to FIGS. 3 and 4, frame member 210a defines four outer surfaces: left side outer surface 331 and opposing right side outer surface 332, top outer surface 333 and opposing bottom outer surface 334, and four inner surfaces: left side inner surface 341 and opposing right side inner surface 342, top inner surface 343 and opposing bottom inner surface 344.

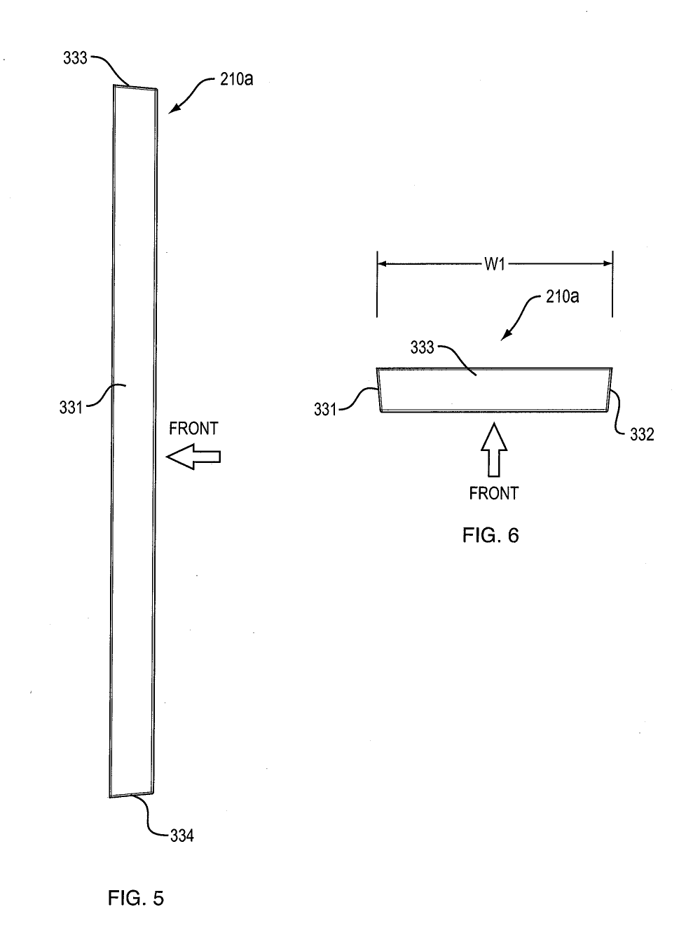

With further reference to FIGS. 5 and 6, in a preferred embodiment, the outer surfaces (331, 332, 333 and 334) slope gently away from open area 320, from the front to the rear of cabinet or enclosure 200. Top outer surface 333 has a gentle upward slope from front to back, and bottom outer surface 334 has a gentle downward slope from front to back. With further reference to FIG. 6, left side outer surface 331 has a gentle outward slope, away from open area 320 from front to back, and right side outer surface 332 has a gentle outward slope, away from open area 320 from front to back. In alternate embodiments, one, two, three or none of the outer surfaces may define a sloped surface. The sloped surfaces function to simply manufacturing, and in particular to simply molding the frame as a single piece.

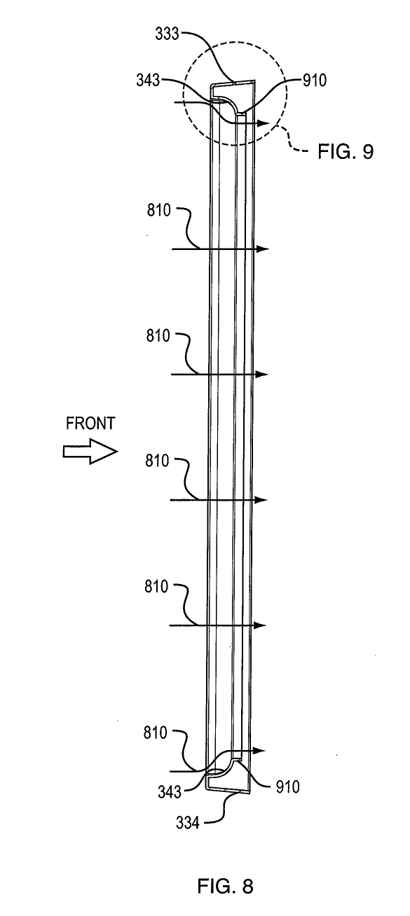

The inner surfaces (341, 342, 343 and 344) are generally curved, and preferably concave, as shown in FIGS. 8, 9, 10, and 11. The curved inner surfaces of frame member 210a are configured to direct the cooling air, shown as references 810 in FIGS. 8, 9 and 10, away from the top, bottom, and sides of the cabinet or enclosure 200 and towards the center of the cabinet or the cabinet or enclosure 200, where the electronic equipment is mounted. Conversely, as with frame member 210b, the curved inner surfaces are configured to direct the heated air away from the top, bottom, and sides of the cabinet and out the rear of the cabinet. In alternate embodiments, one, two, three or none of the inner surfaces may define a curved surface. In additional alternate embodiments, one of more of the inner surfaces may define a slope rather than a curve.

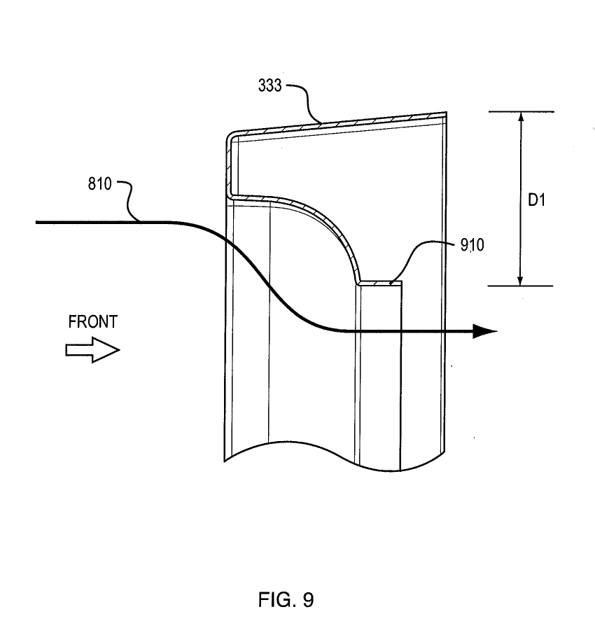

The inner surfaces (341, 342, 343 and 344) are further configured to terminate in a generally flat protrusion 910, shown in FIG. 9, which further directs the cooling air toward the center of the cabinet or enclosure 200 and functions to prevent the cooling air from flowing into the top (or bottom) of the enclosure and over the tops (or under the bottoms) of the electronic components. With frame member 210b, however, protrusion 910 directs the heated out of the cabinet or enclosure 200, and functions to prevent the heated air from flowing back into the top or bottom of the enclosure, and thus prevents the heated air from recirculating within the cabinet or enclosure 200.

In a preferred embodiment, the distance D1 between protrusion 910 and the inner surfaces (341, 342, 343 and 344) is approximately greater than or equal to 2.50 inches (6.4 centimeters).

With further reference to FIG. 7, in a preferred embodiment, frame member 210a defines two vertical, opposing rows of mounting holes 310a and 310b, compliant with EIA standards. The rows of mounting holes 310a and 310b are contiguous with the inner surfaces 341 and 342 and extend into the open area 320. Note that, in alternate embodiments, either or both of the frame members (210a, 210b) may be configured with or without the rows of mounting holes.

IV. Cabinet or Enclosure with Air Flow Management Features—Vertical Rack Mount Rails

An additional preferred embodiment of an inventive cabinet or enclosure 400 with inventive air flow management features is shown in FIG. 14. Cabinet or enclosure 400 is a housing adapted to hold heat-generating equipment within its interior 401, and defines an opening 402 that leads to the interior of the cabinet.

Cabinet or enclosure 400 comprises two vertical front enclosure structural members 110 and 111, two vertical rear enclosure structural members 112 and 113, two horizontal front enclosure structural members 121 and 122, and two horizontal rear enclosure structural members 123 and 124. The enclosure structural members (110, 111, 112, 113, 121, 122, 123, and 124) together form the parallelepiped exterior frame of cabinet or enclosure 400.

Cabinet or enclosure 400 also comprises three pairs of prior art horizontally-mounted rail tracks: lowermost rail tracks 131a and 131b, center rail tracks 132a and 132b, and uppermost rail tracks 133a and 133b. The pairs of horizontally-mounted rail tracks are mounted parallel to each other in a front-to-back orientation, along the left and right sides of enclosure 400. The horizontally-mounted rail tracks preferably span the approximate interior width of cabinet or enclosure 400. Note that neither the number of horizontally-mounted rail tracks, nor their placement within the cabinet or enclosure, is a limitation of the invention.

With further reference to FIG. 14, the inventive vertical rack mount rails 410 and 411 are singular pieces of material that are welded to vertical front enclosure structural members 111 and 110, respectively. Note that the inventive vertical rack mount rails are dual purpose, in that an identical set of inventive vertical rack mount rails may be mounted at the rear of cabinet or enclosure 400, in addition to, or instead of rails 410 and 411.

The inventive vertical rack mount rails 410 and 411 preferably span the entire interior height of the enclosure, and provide a two opposed rows of mounting holes 412a and 412b configured for mounting and supporting the electronic equipment, as would be provided by a pair of opposed vertical mount rails. In this case, the inventive vertical rack mount rails 410 and 411 replace the prior art vertical front rack mount rails 141 and 142 shown in FIGS. 1A and 1B, thus eliminating the gaps 172 and 174 shown in FIG. 1B. Also shown in FIG. 14 are lower threshold 421 and blanking panel 431.

As shown in FIG. 15, in a preferred embodiment, inventive vertical rack mount rail 411 defines an obtuse angle 430. The vertical rack mount rail is angled such that the front face 411a of vertical rack mount rail 411 is offset from the front face 110a of vertical front enclosure structural member 110. This configuration provides a space of approximately two inches to accommodate cabling. In an alternate embodiment, where this space is not required, the front face 4111a of vertical rack mount rail 411 may be flush with the front face 110a of vertical front enclosure structural member 110, as shown in FIG. 16.

The particular construction, materials and dimensions described herein are not limitations of the invention, as other constructions can accomplish the invention described herein.

Although specific features of the invention are shown in some figures and not others, this is for convenience only, as some features may be combined with any or all of the other features in accordance with the invention.

Recitation ranges of values herein are merely intended to serve as a shorthand method of referring individually to each separate value falling within the range, unless otherwise indicated herein, and each separate value is incorporated into the specification as if it were individually recited herein.

1. An assembly for use with a housing, the housing defining an interior that is adapted to hold heat-generating electronic equipment and a first opening that leads to the housing interior, the assembly comprising:
a frame external to the housing and defining a second opening, where the frame is adapted to be coupled to the housing, such that the frame encompasses the first opening, and the first opening is in fluid communication with the second opening; and
where the second opening defines a height and width that are smaller than the height and width of the first opening.

2. The assembly of claim 1, where at least a portion of the second opening is defined by a curved surface of the frame.

3. The assembly of claim 2, where the curved surface is a concave surface.

4. The assembly of claim 1, where at least a portion of the frame defines a sloped surface.

5. The assembly of claim 1, where the frame has a generally parallelepiped shape defined by a top outer surface, a bottom outer surface, and two opposing side outer surfaces; and
where the second opening is generally rectangular in shape and is defined by a top inner surface, a bottom inner surface, and two opposing side inner surfaces.

6. The assembly of claim 5, where at least one of the top inner surface, the bottom inner surface, and the opposing side inner surfaces is a sloped surface.

7. The assembly of claim 5, where at least one of the top inner surface, the bottom inner surface, and the opposing side inner surfaces is a curved surface.

8. The assembly of claim 7, where the curved surface is a concave surface.

9. The assembly of claim 5, where at least the top inner surface and the bottom inner surface are concave surfaces that each terminate in a generally flat protrusion.

10. The assembly of claim 5, where the frame further defines two opposed rows of mounting holes, where each row of mounting holes is contiguous with one of the side inner surfaces.

11. The assembly of claim 10, where the opposed rows of mounting holes are offset from a front face of the frame.

12. An assembly for use with a housing, the housing defining an interior that is adapted to hold heat-generating electronic equipment and a first opening that leads to the housing interior, the assembly comprising:
a frame external to the housing and defining a second opening, where the frame is adapted to be coupled to the housing, such that the frame encompasses the first opening and the first opening is in fluid communication with the second opening;
where the frame has a generally parallelepiped shape defined by a top outer surface, a bottom outer surface, and two opposing side outer surfaces;
where the second opening is generally rectangular in shape and is defined by a curved top inner surface, a curved bottom inner surface, and two opposing curved inner bottom surfaces, and the second opening defines a height and width that are smaller than the height and width of the first opening; and
where the frame further defines two vertical opposed rows of mounting holes that are offset from a front face of the frame, the mounting holes configured to at least partially support the electronic equipment.

13. The assembly of claim 12, where the top inner surface and the bottom inner surface are concave surfaces that each terminate in a generally flat protrusion that extends into the interior of the housing.

14. The assembly of claim 12, where at least one of the top inner surface, the bottom inner surface, and the opposing side inner surfaces is a sloped surface.

15. An enclosure defining an interior that is adapted to hold heat-generating electronic equipment, the enclosure comprising:
a first frame having a generally parallelepiped shape defined by a top outer surface, a bottom outer surface, and two opposing side outer surfaces;
where the first frame defines a generally rectangular opening in fluid communication with the interior, the opening defined by a top inner surface, a bottom inner surface, and two opposing side inner surfaces;
the first frame further defining two opposed rows of mounting holes, where each row of mounting holes is contiguous with one of the side inner surfaces;
a pair of opposed horizontally-mounted rail tracks, where a first end of each rail track is coupled to the first frame;
a pair of opposed vertical rack mount rails, where each rack mount rail is coupled to one of the rail tracks, and each of the rack mount rails defines a plurality of mounting holes;
such that the mounting holes defined in the first frame and the mounting holes defined in the rack mount rails are configured to hold the heat-generating equipment.

16. The enclosure of claim 15, further comprising a second frame opposite the first frame, the second frame defining a generally rectangular opening in fluid communication with the interior, where a second distal end of each of the rail tracks is coupled to the second frame.

17. The enclosure of claim 15, where at least one of the top inner surface, the bottom inner surface, and the opposing side inner surfaces is a curved surface.

18. The enclosure of claim 15, where the top inner surface and the bottom inner surface of the first frame are concave surfaces that each terminate in a generally flat protrusion that extends into the interior of the enclosure.

19. An enclosure defining an interior that is adapted to hold heat-generating electronic equipment, the enclosure comprising:
a generally parallelepiped framework comprised of two pairs of opposed vertical structural members and two pairs of opposed horizontal structural members;
a pair of vertical rails, where each vertical rail defines a first end and a second distal end, and each vertical rail forms an obtuse angle along its length and further defines a plurality of mounting holes proximate the second distal end;
where the first end of each vertical rail is adapted to be coupled to one of the pair of opposing vertical structural members, and the second distal end of each vertical rail extends into the interior of the enclosure;
where the mounting holes in the vertical rails are configured to hold the heat-generating equipment.

20. The enclosure of claim 19, where at least one of the pairs of opposing vertical structural members defines a plurality of mounting holes, such that the mounting holes in the vertical structural members and the mounting holes in the vertical rails are configured to hold the heat-generating equipment.
